(19) United States
(12) Patent Application Publication
(10) Pub. No.: US 2006/0212978 A1
(43) Pub. Date: Sep. 21, 2006

(54) Apparatus and method for reading bit values using microprobe on a cantilever

(76) Inventors: Sarah Brandenberger, Boise, ID (US); Corbin Champion, Tigard, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/081,038

(22) Filed: Mar. 15, 2005

(51) Int. Cl. H01J 37/30

(52) U.S. Cl. 977/858; 977/874

(57) ABSTRACT

Provided is a data storage media has an insulating layer on a doped semiconductor layer, with data recorded thereon as a pattern of pits burned through the insulating layer. A read head for use with this storage media has an array of doped-silicon microprobes in contact with the data storage media, each microprobe of the array is supported by a springy cantilever. As each microprobe nears the substrate a diode junction is formed between the microprobe and the doped semiconductor layer of the media. Conductivity of the junction thus formed is electronically sensed to provide an electronic data stream.

### FIELD

The present document describes read apparatus for reading from a storage medium, of the type wherein the storage medium is mechanically transported across the read apparatus.

### BACKGROUND

Storage devices wherein a storage medium moves relative to read apparatus, where the read apparatus detects data recorded as differences in mechanical, magnetic, optical, or electrical properties of local areas of the media, currently enjoy a huge market. Such devices include optical and magnetic disk and tape drives as are commonly used in computers. These devices typically incorporate read and write apparatus, media, and apparatus for moving the media relative to the read and write apparatus.

In this market, market forces are strong incentives to reduce the bit area, the surface area of media that is allocated for each bit of data stored on the media

Storage devices are being developed using nanotechnology to realize. ultra-small bit areas. One such storage device is based on atomic force microscopy (AFM), in which one, or more microscopic scanning probes are used to read and write to a storage medium.

Typically, scanning probes have sharply pointed tips having tip diameter less than forty (40) nanometers diameter, and in recent implementations about ten nanometers, that contact the storage medium. Storage of data in the storage medium is based on perturbations in the surface of the storage medium detectable by the probes. For example, a perturbation may be a microscopic pit in the storage medium surface, with a pit representing a logical “1,” and the lack of a pit representing a logical “0.”

Previously disclosed techniques for detecting pits in storage media as the media is transported across read apparatus include apparatus that measures heat flow from the read apparatus to the media, and piezoresistive devices that measure variations in position of a part of the read apparatus induced by dents in the media passing by.

It is known that other perturbations useful for data storage include variations in storage medium composition or crystalline phase, filled or empty electronic states, magnetic domain structures or polarization states, chemical bonds in the medium, or atoms moved to or removed from the medium.

### SUMMARY

This invention provides an apparatus and method for reading bit values using a probe on a cantilever.

In particular, and by way of example only, according to an embodiment, provided is a microprobe for sensing data encoded on a media as a pattern of pits in an insulating layer disposed on a semiconductor layer having a first doping, the microprobe including: at least one cantilever having a first conductive arm and a second conductive arm; a contactor formed of a semiconductor material having a second doping, the contactor coupled to the first conductive arm and the second conductive arm of the cantilever, the contactor having a sharp point for sensing the pattern of pits.

### BRIEF DESCRIPTION OF THE DRAWINGS

FIG. 1 is a side view of a single microprobe in contact with the insulating layer of the data storage media.

FIG. 2 is a top view of a single microprobe over the data storage media.

FIG. 3 is an end view of a single microprobe in contact with the insulating layer of the data storage media.

FIG. 4 is a block diagram illustrating data sensing with a microprobe.

FIG. 5 is a top view of a row of an array of microprobes.

FIG. 6 is an abbreviated flow chart of the method for reading data with the microprobes.

FIG. 7 is a bottom view of an alternative mulitiple-row array of interdigitated microprobes.

### DETAILED DESCRIPTION

Before proceeding with the detailed description, it is to be appreciated that the present teaching is by way of example, not by limitation. The concepts herein are not limited to use or application with a specific apparatus and method for reading data from a storage medium. Thus, although the instrumentalities described herein are for the convenience of explanation, shown and described with respect to exemplary embodiments, it will be appreciated that the principles herein may be equally applied in other types of data storage devices.

In the following description, the term “data” is understood and appreciated to be represented in various ways depending upon context. Generally speaking, the data at issue is primarily binary in nature, represented as logic “0” and logic “1”. However, it will be appreciated that the binary states in practice may be represented by relatively different voltages, currents, resistances or the like that may be measured or sensed, and it may be a matter of design choice whether a particular practical manifestation of data within a data storage media represents a “0” or a “1” or other memory state designation.

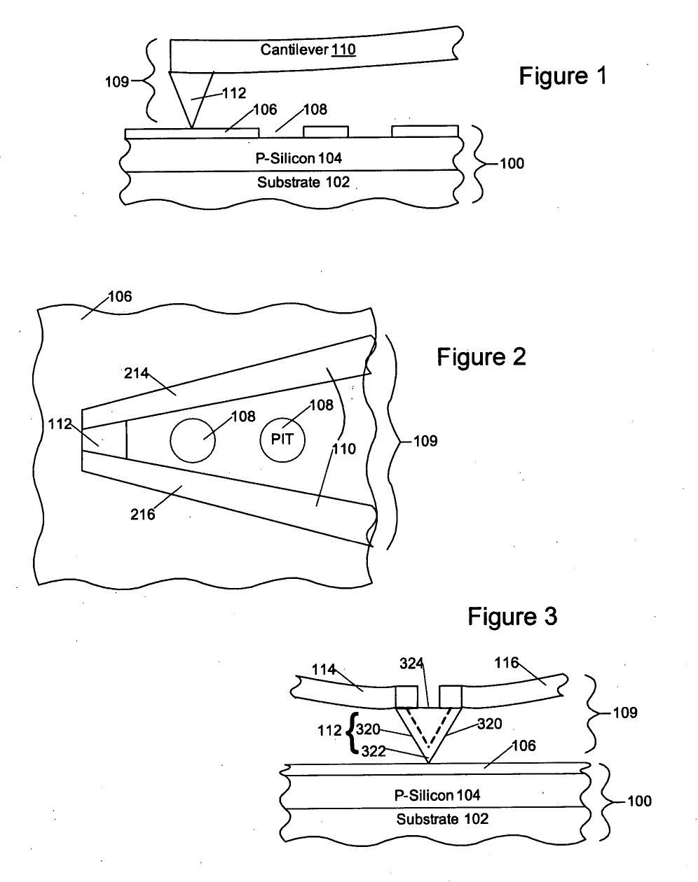

With reference to FIGS. 1, 2, and 3; a data storage media 100 has a substrate 102 coated with a semiconductor layer 104. In an embodiment, the semiconductor layer 104 of the storage media is doped P-type. Semiconductor layer 104 is coated with an insulating film 106. Data is recorded as a pattern of perturbations, here the perturbations are openings 108 or pits in insulating film 106. In a particular embodiment, insulating film 106 is a layer of a thermoplastic polymer such as polymethylmethacrylate.

A read device incorporates a microprobe 109 to sense the openings 108 in the insulating film 106. The microprobe 109 incorporates V-shaped cantilever 110 as a springy support for a contactor 112 located near the angle of the V. The cantilever 110 has a first conductive arm 214 and a second conductive arm 216 (FIGS. 2 & 3), additional nonconductive components may be present in each arm 214, 216 and on the cantilever 110. Contactor 112 is made of a semiconductor material. In an embodiment, contactor 112 is made of N-type silicon more heavily doped along its sides 320 and tip 322 (FIG. 3), while more lightly doped at its base 324.

Contactor 112 (FIGS. 1, 2, and 3) and cantilever 110 are fabricated through thin-film and photoetching techniques as is becoming common in nanotechnology. Cantilever 110 is less than thirty (30) microns wide, in an embodiment it is approximately sixteen (16) microns wide and twenty-seven (27) microns long, with a twenty-degree (20°) angle between first conductive arm 214 and second conductive arm 216.

Tips of the contactors 112 are sharpened to an effective tip diameter of less than forty (40) nanometers, and preferably between about ten (10) and twenty (20) nanometers diameter. Contactors 112 are sharpened through anisotropic etching.

When it is desired to read data from the data storage media, the contactor 112 is allowed to contact the surface of the media, while the media undergoes motion relative to the contactor 112. The cantilever arms 214, 216 are slightly flexed by forces applied to the contactor 112.

In an embodiment, the media has the form of a rotating disk, and the microprobe 109 array is stationary. In an alternative embodiment, the microprobe 109 moves relative to a stationary media. In yet another embodiment, the media has the form of a disk rotating under the microprobe array, which in turn has the ability to move radially with respect to the disk.

Where insulating film 106 is present on the media surface, the contactor 112 rides upon the insulating film 106 as media 100 and microprobe 109 move. Where a pit or opening 108 is present, the springy cantilever arms 214, 216 straighten slightly such that contactor 112 dips into the pit 108 to contact the semiconductor layer 104.

Perfect contact is not required, since tunneling conduction occurs when the insulating film 106 is sufficiently thin and contactor 112 is sufficiently close to semiconductor layer 104. When the tip of the contactor 112 contacts the semiconductor layer 104, an effective diode junction is formed.

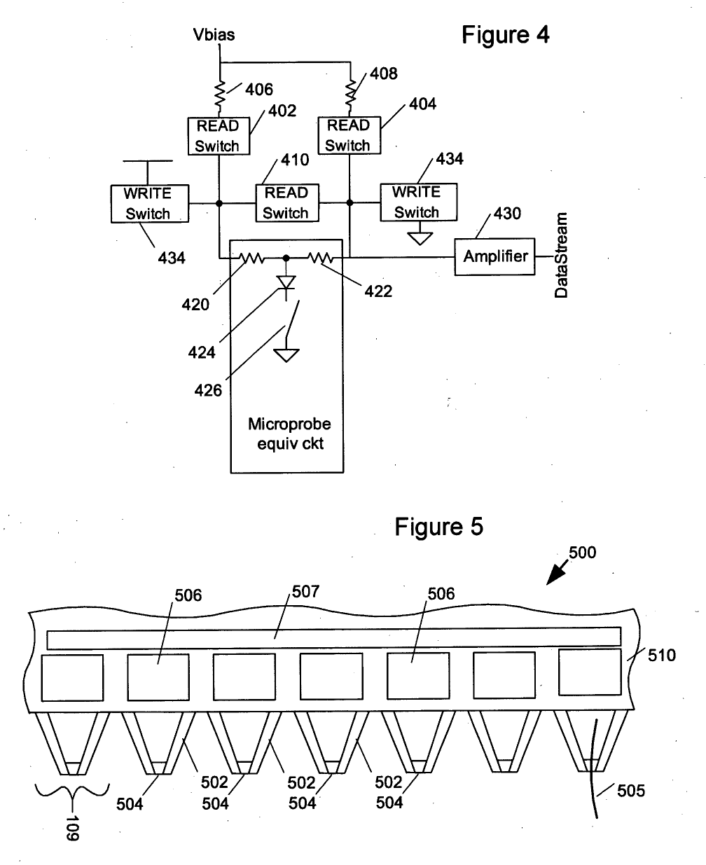

As illustrated in FIG. 4, each microprobe 109 has associated sensing circuitry suitable for detecting electrical conductivity differences between a state when contactor 112 rides on the insulating film 106, and a state when the contactor 112 has dropped into a pit 108 and the diode junction has formed. In other words, detection of a data represented by an opening 108 may be recognized and distinguished from data represented by the absence of an opening by a the change in conductivity between the diode-absent state and the diode-present state as sensed by sensing circuitry.

FIG. 4 illustrates the read electronics, also known as sensing circuitry, for reading of data from the media. During reading, the microprobe is biased through read switches 402, 404 and resistors 406, 408 coupled to a bias supply Vbias. Read switch 410 connects the two cantilever arms 214, 216 of the cantilever (FIGS. 2 & 3) together.

The microprobe structure has an equivalent circuit comprising resistors 420, 422, representing parasitic electrical resistance of the cantilever arms 214, 216 as well as resistance of the semiconductor contactor 112. The equivalent circuit also has diode 424, switch 426, and diode resistor 428.

When the microprobe's 109 contactor 112 rides on full-thickness insulating film 106, switch 426 is open and current does not flow in diode 424, leaving voltage at the microprobe at the biased level. In at least one embodiment, this biased level is representative of logical 1.

When the microprobe's 109 contactor 112 approaches sufficiently close to, or comes in contact with, the semiconductor layer 104 of the media; switch 426 of this model closes and current flow in diode 424, diode resistor 428 and switch 426 reduces voltage at the microprobe sufficiently that amplifier 430 can detect a voltage drop. In at least one embodiment, this dropped voltage is representative of logical 0.

The sequence of bias-level voltages and dropped voltages are used to reconstruct a data stream representing the stored data. For example, user data such as “28088” may be represented in binary form as “110110110111000” by a series of appropriately spaced smooth spaces and openings 108 in insulating film 106.

Other methods of sensing current flow in diode 424 may be used. In one alternative embodiment, the sense amplifier is located in the semiconducting substrate of the media instead of in the microprobe array.

In an embodiment of the read apparatus 500 illustrated in the top view of FIG. 5, there is an array of one or more parallel linear rows of many microprobes 109 of which one row is shown. Each microprobe 109 has cantilevers 502 supporting a contactor 504 riding on a rotating disk (not shown), each contactor 504 of the array tracing a circular track 505 around a disk as the disk rotates under the microprobe array.

Each microprobe 109 has associated sensing electronics 506 for generating a data stream according to a pattern of pits on the disk. In this embodiment, with multiple microprobes in an array, selection electronics 507 selects one or more data streams from amplifiers 230 of the array for further processing.

In a particular embodiment of the read apparatus 500, there are eight rows of microprobes 109, where cantilevers occur every forty-five (45) microns in each row. The microprobes of the rows are interdigitated such that the array has an effective track spacing of under six microns;

The cantilevers 502 are fabricated on the lower surface of a silicon wafer 510, which has been etched back to free all but an attachment portion of the cantilevers 502 and to allow the cantilevers 502 to flex. On the remaining portion of the silicon wafer 510 are sensing circuitry 506, including bias resistors and amplifiers, associated with each cantilever 502 and microprobe 504.

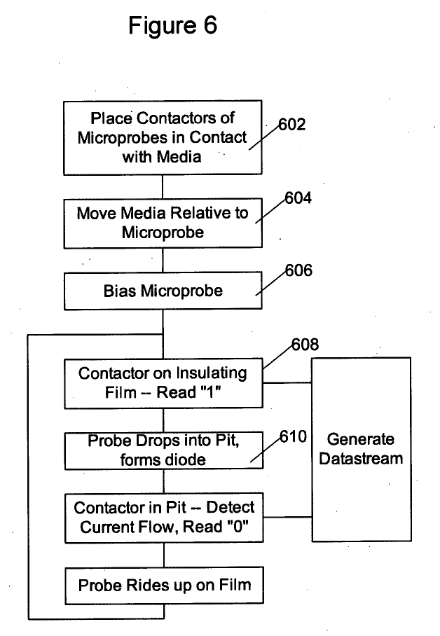

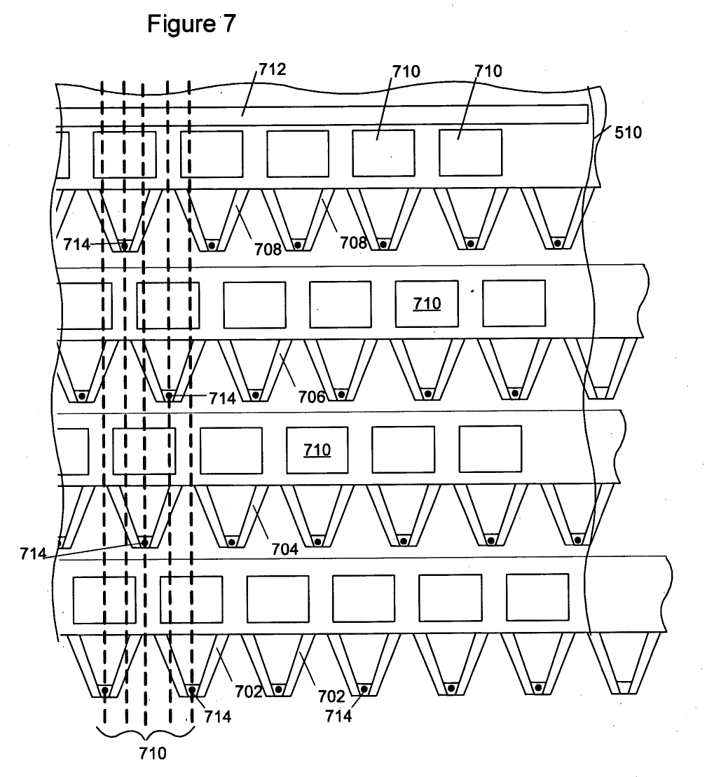

The method of reading data is summarized in FIG. 6, with reference to FIGS. 1-4. The contactors 112 of the microprobes 109 are placed 602 into contact with the surface of the media and appropriate forces applied to slightly flex the cantilevers 110. The media is moved 604 relative to the microprobe and electrical bias applied 606 to the microprobe. When the contactors 112 are on full thickness film, a first logic value which might be a logic 1 is read 608; while when the contactors 112 drop into pits, the diode forms 610, current flow is detected, and a second logic value which might be a logic 0 is read 612.

Insulating film 106 is initially smooth (i.e., does not contain openings 108). The data values initially present in data storage media 100 are all the same, and for example are conventionally recognized as logical “1”. The creation of an opening 108 therefore represents a logical “0”. In alternative embodiments, this relationship may be reversed such that the initial data values are recognized as logical “0” and the creation of an opening 108 is recognized as logical “1”.

Writing of data onto the media can be done in several ways. In an embodiment, write switches 434 associated with selected microprobes 109 turn on at selected points during relative motion of media 100 and microprobes 109 such that the contactor 112 heats momentarily, due to current flow in the contactor resistance modeled by resistors 420, 422 of the equivalent circuit of FIG. 4, and contactor 112 sinks under tension of cantilever arms 214, 216, into thermoplastic insulating film 106 leaving a pit 108. When write switches 434 are turned off, contactor 109 cools off to the point where it can no longer sink into the thermoplastic insulating film 106, and, as the media 100 continues to move relative to the microprobe 109, the contactor 112 rides up upon the surface of the insulating film 106.

By electronically controlling which microprobes heat at which times, a pattern of pits 108 may be generated on the media In an alternative embodiment writing is done optically, by burning away insulating film 106 where pits are desired.

In another alternative embodiment, writing the media is performed through a method similar to that of stamping DVD's. A master is generated by selectively burning a pattern of pits into a surface of a master with an electron beam. The master is then electroplated with nickel to create a negative punch having raised portions corresponding to a desired pattern of pits. The negative punch may, but need not, be replicated through an intermediate positive to a secondary negative punch.

Blank media 100, having a smooth insulating film 106, is heated, the negative punch is then pressed into the insulating film 106, displacing portions of the film 106 to leave pits 108. The negative punch is then removed from the media 100 leaving a pattern of pits 108. The pattern of pits 108 contains data corresponding to data encoded in the pattern of pits burned into the master by the electron beam.

An alternative embodiment having an array with four rows of interdigitated microprobes is illustrated in FIG. 7. In this embodiment, there are microprobes 702 in a first row, microprobes 704 in a second row, microprobes 706 in a third row, and microprobes 708 in a fourth row. Each microprobe is associated with sense electronics 710. Each sense electronics feeds to data selection electronics 712. The sharpened points of the contactors 714 of the microprobes are interdigitated to trace interleaved tracks 716 on the media as the media is translated past the array.

While the microprobe and associated read circuitry has been particularly shown and described with reference to a preferred embodiment thereof, it will be understood by those skilled in the art that various changes may be made in the above methods, systems and structures without departing from the scope hereof. It should thus be noted that the matter contained in the above description and/or shown in the accompanying drawings should be interpreted as illustrative and not in a limiting sense. The following claims are intended to cover all generic and specific features described herein, as well as all statements of the scope of the present method, system and structure, which, as a matter of language, might be said to fall therebetween.

What is claimed is:

1. A microprobe for sensing data encoded on a media as a pattern of pits in an insulating layer disposed on a semiconductor layer having a first doping, the microprobe comprising:
at least one cantilever having a first conductive arm and a second conductive arm;
a contactor formed of a semiconductor material having a second doping, the contactor coupled to the first conductive arm and the second conductive arm of the cantilever, the contactor having a sharp point for sensing the pattern of pits.

2. The microprobe of claim 1, wherein the contactor is sharpened to a tip diameter of less than 40 nanometers.

3. The microprobe of claim 2, wherein the contactor is sharpened to a tip diameter of less than 20 nanometers.

4. The microprobe of claim 1, wherein a distance from an outer edge of the first conductive arm and an outer edge of the second conductive arm is less than 30 microns.

5. An array of microprobes for sensing data encoded as a pattern of pits in an insulating layer superimposed on a semiconductor layer having a first doping, each microprobe of the array comprising:
at least one cantilever having a first conductive arm and a second conductive arm;
a contactor formed of a semiconductor material having a second doping, the contactor coupled to the first conductive arm and the second conductive arm of the cantilever, the contactor having a sharp point for sensing the pattern of pits.

6. The array of microprobes of claim 5, wherein the contactor of each microprobe of the array is sharpened to a tip diameter of less than 40 nanometers.

7. The array of microprobes of claim 6, wherein the contactor of each microprobe of the array is sharpened to a tip diameter of less than 20 nanometers.

8. The array of microprobes of claim 5, wherein the array comprises at least one row of microprobes and wherein each microprobe of the array has associated sensing electronics.

9. The array of microprobes of claim 8, wherein the array comprises at least four rows of microprobes.

10. A read apparatus for sensing data encoded as a pattern of pits in an insulating layer superimposed on a semiconductor layer having a first doping, the read apparatus comprising an array of microprobes, wherein each microprobe comprises:
at least one cantilever having a first conductive arm and a second conductive arm;
a contactor formed of a semiconductor material having a second doping, the contactor coupled to the first conductive arm and the second conductive arm of the cantilever, the contactor having a sharp point for sensing the pattern of pits;
read electronics coupled to at least the first conductive arm of the cantilever, the read electronics comprising at least one bias resistor and a sense amplifier.

11. The array of microprobes of claim 10, wherein the contactor of each microprobe of the array is sharpened to a tip diameter of less than 20 nanometers.

12. The array of microprobes of claim 11, wherein the array comprises at least one row of microprobes.

13. The array of microprobes of claim 12, wherein the array comprises at least four rows of microprobes.

14. A method of sensing data on a recording media, the data encoded on the media as pits in an insulating layer disposed upon a doped semiconductor layer, comprising:
contacting the media with a microprobe comprising a contactor mounted on a springy cantilever, the contactor fabricated from a semiconducting material;
inducing relative motion between the media and the microprobe;
biasing the microprobe;
allowing a sharp point of the contactor of the microprobe to drop into pits of the insulating layer, thereby forming a diode between the contactor and the doped semiconductor layer of the media;
detecting current flow in the diode formed by the contactor and the doped semiconductor layer of the media.

15. The method of claim 14, wherein the springy cantilever comprises a first conductive arm and a second conductive arm.

16. The method of claim 14, wherein the sharp point of the contactor is sharpened to a tip diameter of less than 40 nanometers.

17. The method of claim 16, wherein the sharp point of the contactor is sharpened to a tip diameter of less than 20 nanometers.

18. The method of claim 14, wherein the microprobe is electronically selected from among an array of microprobes.

19. The method of claim 18, wherein the array of microprobes comprises at least four rows of microprobes and wherein microprobes of each row of microprobes have a pitch of less than fifty microns.

20. The method of claim 19, wherein the microprobes of a first row of microprobes of the array of microprobes are interdigitated between microprobes of a second row.
